(19) United States
(12) Patent Application Publication
(10) Pub. No.: US 2022/0151117 A1
(43) Pub. Date: May 12, 2022

(54) Electronic Module

(71) Applicant: Ticona LLC, Florence, KY (US)

(72) Inventors: Suresh Subramonian, Cary, NC (US); Prabuddha Bansal, Florence, KY (US); Young-Chul Yang, Seoul (KR); SooHee Choi, Gyeonggi-do Province (KR); Arno Wolf, Schonau (DE)

(21) Appl. No.: 17/522,022

(22) Filed: Nov. 9, 2021

Related U.S. Application Data
(60) Provisional application No. 63/235,268, filed on Aug. 20, 2021.
(60) Provisional application No. 63/111,866, filed on Nov. 10, 2020.

(51) Int. Cl. H05K 9/00; G01S 7/481; G01S 7/02; C08L 77/06; C08G 63/183; C08K 3/04; C08L 87/00; H01Q 1/24; H01Q 1/52

(52) U.S. Cl. CPC H05K 9/009; G01S 7/4818; G01S 7/027; C08L 77/06; C08G 63/183; C08L 2205/02; C08L 87/00; H01Q 1/246; H01Q 1/526; C08L 2203/206; C08K 3/04

(57) ABSTRACT

An electronic module that comprises a housing that receives at least one electronic component is disclosed. The housing contains a polymer composition that includes an electromagnetic interference filler distributed within a polymer matrix, wherein the electromagnetic interference filler includes a plurality of carbon fibers and the polymer matrix contains a thermoplastic polymer. Further, the composition exhibits an electromagnetic interference shielding effectiveness of about 30 decibels or more, as determined in accordance with ASTM D4935-18 at a frequency of 5 GHz and thickness of 1 millimeter, and an in-plane thermal conductivity of about 1 W/m-K or more, as determined in accordance with ASTM E 1461-13.

### CROSS REFERENCE TO RELATED APPLICATIONS

The present application claims filing benefit of U.S. Provisional Patent Applications Ser. No. 63/111,866 having a filing date of Nov. 10, 2020 and 63/235,268 having a filing date of Aug. 20, 2021, which are incorporated herein by reference in their entirety.

### BACKGROUND OF THE INVENTION

Electronic modules typically contain electronic components (e.g., printed circuit board, antenna elements, radio frequency devices, sensors, light sensing and/or transmitting elements (e.g., fibers optics), cameras, global positioning devices, etc.) that are received within a housing structure to protect them from weather, such as sunlight, wind, and moisture. Typically, such housings are formed from materials that allow the passage of electromagnetic signals (e.g., radiofrequency signals or light). While these materials are suitable in some applications, problems can nevertheless occur at higher frequency ranges, such as those associated with LTE or 5G systems. A radar module, for instance, typically contains one or more printed circuit boards having electrical components dedicated to handling radio frequency (RF) radar signals, digital signal processing tasks, etc. To ensure that these components operate effectively at high frequencies, they are generally received in a housing structure and then covered with a radome that is transparent to radio waves. Because other surrounding electrical devices can generate electromagnetic interference (“EMI”) that can impact the accurate operation of the radar module, an EMI shield (e.g., aluminum plate) is generally positioned between the housing and printed circuit board. In addition to protecting the components from electromagnetic interference, it is also generally necessary to employ a heat sink (e.g., thermal pad) on the circuit board to help draw heat away from the components. Unfortunately, the addition of such components can add a substantial amount of cost and weight to the resulting module, which is particularly disadvantageous as the automotive industry is continuing to require smaller and lighter components. As such, a need currently exists for an electronic module that does not require the need for additional EMI shields and/or heat sinks.

### SUMMARY OF THE INVENTION

In accordance with one embodiment of the present invention, an electronic module (e.g., antenna module, radar module, lidar module, camera module, etc.) is disclosed that comprises a housing that receives at least one electronic component. The housing contains a polymer composition that includes an electromagnetic interference filler distributed within a polymer matrix, wherein the electromagnetic interference filler includes a plurality of carbon fibers and the polymer matrix contains a thermoplastic polymer. Further, the composition exhibits an electromagnetic interference shielding effectiveness of about 30 decibels or more, as determined in accordance with ASTM D4935-18 at a frequency of 5 GHz and thickness of 1.6 millimeters, and an in-plane thermal conductivity of about 1 W/m-K or more, as determined in accordance with ASTM E 1461-13.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 is an exploded perspective view of one embodiment of an electronic module that may employ the polymer composition of the present invention;

FIG. 2 depicts one embodiment of a 5G system that may employ an electronic module of the present invention; and

FIG. 3 is a graph showing the shielding effectiveness (“SE”) for Samples 1-2 (thickness of 1.6 mm) over a frequency range from 1.5 GHz to 10 GHz.

### DETAILED DESCRIPTION

It is to be understood by one of ordinary skill in the art that the present discussion is a description of exemplary embodiments only, and is not intended as limiting the broader aspects of the present invention.

Generally speaking, the present invention is directed to an electronic module that contains a housing that receives one or more electronic components (e.g., printed circuit board, antenna elements, radio frequency sensing devices, sensors, light sensing and/or transmitting elements (e.g., fibers optics), cameras, global positioning devices, etc.). The housing contains a polymer composition comprising an EMI shielding filler distributed within a polymer matrix. The polymer matrix contains a high performance, thermoplastic polymer and the EMI shielding filler includes carbon fibers having a combination of a high degree of intrinsic thermal conductivity and a low intrinsic electrical resistivity.

Through careful selection of the particular nature and concentration of these components, the resulting composition can exhibit a unique combination of thermal conductivity and EMI shielding effectiveness at high frequency ranges. More particularly, the EMI shielding effectiveness (“SE”) may be about 30 decibels (dB) or more, in some embodiments about 32 dB or more, and in some embodiments, from about 35 dB to about 100 dB, as determined in accordance with ASTM D4935-18 at a high frequency, such as 5 GHz. Notably, it has been discovered that the EMI shielding effectiveness may remain stable over a high frequency range, including 5G frequencies, such as about 1.5 GHz or more, in some embodiments from about 1.5 GHz to about 18 GHz, in some embodiments from about 1.5 GHz to about 10 GHz, and in some embodiments, from about 2 GHz to about 9 GHz. The EMI shielding effectiveness may also be within the desired range for a variety of different part thicknesses, such as from about 0.5 to about 10 millimeters, in some embodiments from about 0.8 to about 5 millimeters, and in some embodiments, from about 1 to about 4 millimeters (e.g., 1 millimeter, 1.6 millimeters, or 3 millimeters). Within these high frequency and/or thickness ranges, for example, the average EMI shielding effectiveness may be about 30 dB or more, in some embodiments about 32 dB or more, and in some embodiments, from about 35 dB to about 100 dB. Likewise, the minimum EMI shielding effectiveness may be about 30 dB or more, in some embodiments about 32 dB or more, and in some embodiments, from about 35 dB to about 100 dB. In addition to exhibiting good EMI shielding effectiveness, the composition may also exhibit a relatively low volume resistivity as determined in accordance with ASTM D257-14, such as about 25,000 ohm-cm or less, in some embodiments about 20,000 ohm-cm or less, in some embodiments about 10,000 ohm-cm or less, in some embodiments about 5,000 ohm-cm or less, in some embodiments about 1,000 ohm-cm or less, and in some embodiments, from about 50 to about 800 ohm-cm.

The polymer composition is also thermally conductive and thus may exhibit an in-plane thermal conductivity of about 1 W/m-K or more, in some embodiments about 3 W/m-K or more, in some embodiments about 5 W/m-K or more, in some embodiments from about 7 to about 50 W/m-K, and in some embodiments, from about 10 to about 35 W/m-K, as determined in accordance with ASTM E 1461-13. The composition may also exhibit a through-plane thermal conductivity of about 0.3 W/m-K or more, in some embodiments about 0.5 W/m-K or more, in some embodiments about 0.40 W/m-K or more, in some embodiments from about 1 to about 15 W/m-K, and in some embodiments, from about 1 to about 10 W/m-K, as determined in accordance with ASTM E 1461-13.

Conventionally, it was believed that polymer compositions exhibiting good EMI shielding effectiveness, as well as low volume resistivity and/or thermal conductivity, would not also possess sufficiently mechanical properties. It has been discovered, however, that the polymer composition is still able to maintain excellent mechanical properties. For example, the polymer composition may exhibit a Charpy unnotched impact strength of about 20 kJ/m² or more, in some embodiments from about 30 to about 80 kJ/m², and in some embodiments, from about 40 to about 60 kJ/m², measured at according to ISO Test No. 179-1:2010) (technically equivalent to ASTM D256-10e1) at various temperatures, such as within a temperature range of from about −50° C. to about 85° C. (e.g., 23° C.). The tensile and flexural mechanical properties may also be good. For example, the polymer composition may exhibit a tensile strength of about 50 MPa or more, in some embodiments from about 50 MPa or more 300 MPa, in some embodiments from about 80 to about 500 MPa, and in some embodiments, from about 85 to about 250 MPa; a tensile break strain of about 0.1% or more, in some embodiments from about 0.2% to about 5%, and in some embodiments, from about 0.3% to about 2.5%; and/or a tensile modulus of from about 3,500 MPa to about 30,000 MPa, in some embodiments from about 6,000 MPa to about 28,000 MPa, and in some embodiments, from about 15,000 MPa to about 25,000 MPa. The tensile properties may be determined in accordance with ISO Test No. 527-1:2019 (technically equivalent to ASTM D638-14) at various temperatures, such as within a temperature range of from about −50° C. to about 85° C. (e.g., 23° C.). The polymer composition may also exhibit a flexural strength of from about 100 to about 500 MPa, in some embodiments from about 130 to about 400 MPa, and in some embodiments, from about 140 to about 250 MPa; a flexural break strain of about 0.5% or more, in some embodiments from about 0.6% to about 5%, and in some embodiments, from about 0.7% to about 2.5%; and/or a flexural modulus of from about 5,000 MPa to about 60,000 MPa, in some embodiments from about 20,000 MPa to about 55,000 MPa, and in some embodiments, from about 30,000 MPa to about 50,000 MPa. The flexural properties may be determined in accordance with ISO Test No. 178:2019 (technically equivalent to ASTM D790-17) at various temperatures, such as within a temperature range of from about −50° C. to about 85° C. (e.g., 23° C.).

The polymer composition may also exhibit a low dielectric constant and dissipation factor at high frequencies, such as noted above. That is, the polymer composition may exhibit a low dielectric constant of about 4 or less, in some embodiments about 3.5 or less, in some embodiments from about 0.1 to about 3.4 and in some embodiments, from about 1 to about 3.3, in some embodiments, from about 1.5 to about 3.2, in some embodiments from about 2 to about 3.1, and in some embodiments, from about 2.5 to about 3.1 at high frequencies (e.g., 2 or 10 GHz). The dissipation factor of the polymer composition, which is a measure of the loss rate of energy, may likewise be about 0.001 or less, in some embodiments about 0.0009 or less, in some embodiments about 0.0008 or less, in some embodiments, about 0.0007 or less, in some embodiments about 0.0006 or less, and in some embodiments, from about 0.0001 to about 0.0005 at high frequencies (e.g., 2 or 10 GHz).

Various embodiments of the present invention will now be described in more detail.

### I. Polymer Matrix

A. Thermoplastic Polymers

The polymer matrix generally employs one or more high performance, thermoplastic polymers having a high degree of heat resistance, such as reflected by a deflection temperature under load (“DTUL”) of about 40° C. or more, in some embodiments about 50° C. or more, in some embodiments about 60° C. or more, in some embodiments from about from about 80° C. to about 250° C., and in some embodiments, from about 100° C. to about 200° C., as determined in accordance with ISO 75-2:2013 at a load of 1.8 MPa. In addition to exhibiting a high degree of heat resistance, the thermoplastic polymers also typically have a high glass transition temperature, such as about 10° C. or more, in some embodiments about 20° C. or more, in some embodiments about 30° C. or more, in some embodiments about 40° C. or more, in some embodiments about 50° C. or more, and in some embodiments, from about 60° C. to about 320° C. When semi-crystalline or crystalline polymers are employed, the high performance polymers may also have a high melting temperature, such as about 140° C. or more, in some embodiments from about 150° C. to about 400° C., and in some embodiments, from about 200° C. to about 380° C. The glass transition and melting temperatures may be determined as is well known in the art using differential scanning calorimetry (“DSC”), such as determined by ISO 11357-2:2020 (glass transition) and 11357-3:2018 (melting).

Suitable high performance, thermoplastic polymers for this purpose may include, for instance, polyolefins (e.g., ethylene polymers, propylene polymers, etc.), polyamides (e.g., aliphatic, semi-aromatic, or aromatic polyamides), polyesters, polyarylene sulfides, liquid crystalline polymers (e.g., wholly aromatic polyesters, polyesteramides, etc.), polycarbonates, polyethers (e.g., polyoxymethylene), etc., as well as blends thereof. The exact choice of the polymer system will depend upon a variety of factors, such as the nature of other fillers included within the composition, the manner in which the composition is formed and/or processed, and the specific requirements of the intended application.

Aromatic polymers, for instance, are particularly suitable for use in the polymer matrix. The aromatic polymers can be substantially amorphous, semi-crystalline, or crystalline in nature. One example of a suitable semi-crystalline aromatic polymer, for instance, is an aromatic polyester, which may be a condensation product of at least one diol (e.g., aliphatic and/or cycloaliphatic) with at least one aromatic dicarboxylic acid, such as those having from 4 to 20 carbon atoms, and in some embodiments, from 8 to 14 carbon atoms. Suitable diols may include, for instance, neopentyl glycol, cyclohexanedimethanol, 2,2-dimethyl-1,3-propane diol and aliphatic glycols of the formula HO(CH₂)ₙOH where n is an integer of 2 to 10. Suitable aromatic dicarboxylic acids may include, for instance, isophthalic acid, terephthalic acid, 1,2-di(p-carboxyphenyl)ethane, 4,4′-dicarboxydiphenyl ether, etc., as well as combinations thereof. Fused rings can also be present such as in 1,4- or 1,5- or 2,6-naphthalene-dicarboxylic acids. Particular examples of such aromatic polyesters may include, for instance, poly(ethylene terephthalate) (PET), poly(1,4-butylene terephthalate) (PBT), poly(1,3-propylene terephthalate) (PPT), poly(1,4-butylene 2,6-naphthalate) (PBN), poly(ethylene 2,6-naphthalate) (PEN), poly(1,4-cyclohexylene dimethylene terephthalate) (PCT), as well as mixtures of the foregoing.

Derivatives and/or copolymers of aromatic polyesters (e.g., polyethylene terephthalate) may also be employed. For instance, in one embodiment, a modifying acid and/or diol may be used to form a derivative of such polymers. As used herein, the terms “modifying acid” and “modifying diol” are meant to define compounds that can form part of the acid and diol repeat units of a polyester, respectively, and which can modify a polyester to reduce its crystallinity or render the polyester amorphous. Examples of modifying acid components may include, but are not limited to, isophthalic acid, phthalic acid, 1,3-cyclohexanedicarboxylic acid, 1,4-cyclohexane dicarboxylic acid, 2,6-naphthaline dicarboxylic acid, succinic acid, glutaric acid, adipic acid, sebacic acid, suberic acid, 1,12-dodecanedioic acid, etc. In practice, it is often preferable to use a functional acid derivative thereof such as the dimethyl, diethyl, or dipropyl ester of the dicarboxylic acid. The anhydrides or acid halides of these acids also may be employed where practical. Examples of modifying diol components may include, but are not limited to, neopentyl glycol, 1,4-cyclohexanedimethanol, 1,2-propanediol, 1,3-propanediol, 2-methy-1,3-propanediol, 1,4-butanediol, 1,6-hexanediol, 1,2-cyclohexanediol, 1,4-cyclohexanediol, 1,2-cyclohexanedimethanol, 1,3-cyclohexanedimethanol, 2,2,4,4-tetramethyl 1,3-cyclobutane diol, Z,8-bis(hydroxymethyltricyclo-[5.2.1.0]-decane wherein Z represents 3, 4, or 5; 1,4-bis(2-hydroxyethoxy)benzene, 4,4′-bis(2-hydroxyethoxy) diphenylether [bis-hydroxyethyl bisphenol A], 4,4′-Bis(2-hydroxyethoxy)diphenylsulfide [bis-hydroxyethyl bisphenol S] and diols containing one or more oxygen atoms in the chain, e.g. diethylene glycol, triethylene glycol, dipropylene glycol, tripropylene glycol, etc. In general, these diols contain 2 to 18, and in some embodiments, 2 to 8 carbon atoms. Cycloaliphatic diols can be employed in their cis- or trans-configuration or as mixtures of both forms.

The aromatic polyesters, such as described above, typically have a DTUL value of from about 40° C. to about 80° C., in some embodiments from about 45° C. to about 75° C., and in some embodiments, from about 50° C. to about 70° C. as determined in accordance with ISO 75-2:2013 at a load of 1.8 MPa. The aromatic polyesters likewise typically have a glass transition temperature of from about 30° C. to about 120° C., in some embodiments from about 40° C. to about 110° C., and in some embodiments, from about 50° C. to about 100° C., such as determined by ISO 11357-2:2020, as well as a melting temperature of from about 170° C. to about 300° C., in some embodiments from about 190° C. to about 280° C., and in some embodiments, from about 210° C. to about 260° C., such as determined in accordance with ISO 11357-2:2018. The aromatic polyesters may also have an intrinsic viscosity of from about 0.1 dl/g to about 6 dl/g, in some embodiments from about 0.2 to about 5 dl/g, and in some embodiments from about 0.3 to about 1 dl/g, such as determined in accordance with ISO 1628-5:1998.

Polyarylene sulfides are also suitable semi-crystalline aromatic polymers. The polyarylene sulfide may be homopolymers or copolymers. For instance, selective combination of dihaloaromatic compounds can result in a polyarylene sulfide copolymer containing not less than two different units. For instance, when p-dichlorobenzene is used in combination with m-dichlorobenzene or 4,4′-dichlorodiphenylsulfone, a polyarylene sulfide copolymer can be formed containing segments having the structure of formula:

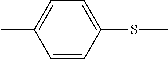

and segments having the structure of formula:

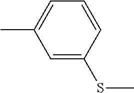

or segments having the structure of formula:

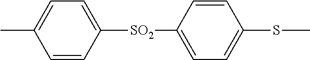

The polyarylene sulfide may be linear, semi-linear, branched or crosslinked. Linear polyarylene sulfides typically contain 80 mol % or more of the repeating unit -(Ar-S)—. Such linear polymers may also include a small amount of a branching unit or a cross-linking unit, but the amount of branching or cross-linking units is typically less than about 1 mol % of the total monomer units of the polyarylene sulfide. A linear polyarylene sulfide polymer may be a random copolymer or a block copolymer containing the above-mentioned repeating unit. Semi-linear polyarylene sulfides may likewise have a cross-linking structure or a branched structure introduced into the polymer a small amount of one or more monomers having three or more reactive functional groups. By way of example, monomer components used in forming a semi-linear polyarylene sulfide can include an amount of polyhaloaromatic compounds having two or more halogen substituents per molecule which can be utilized in preparing branched polymers. Such monomers can be represented by the formula R′Xₙ, where each X is selected from chlorine, bromine, and iodine, n is an integer of 3 to 6, and R′ is a polyvalent aromatic radical of valence n which can have up to about 4 methyl substituents, the total number of carbon atoms in R′ being within the range of 6 to about 16. Examples of some polyhaloaromatic compounds having more than two halogens substituted per molecule that can be employed in forming a semi-linear polyarylene sulfide include 1,2,3-trichlorobenzene, 1,2,4-trichlorobenzene, 1,3-dichloro-5-bromobenzene, 1,2,4-triiodobenzene, 1,2,3,5-tetrabromobenzene, hexachlorobenzene, 1,3,5-trichloro-2,4,6-trimethylbenzene, 2,2′,4,4′-tetrachlorobiphenyl, 2,2′,5,5′-tetra-iodobiphenyl, 2,2′,6,6′-tetrabromo-3,3′,5,5′-tetramethylbiphenyl, 1,2,3,4-tetrachloronaphthalene, 1,2,4-tribromo-6-methylnaphthalene, etc., and mixtures thereof.

The polyarylene sulfides, such as described above, typically have a DTUL value of from about 70° C. to about 220° C., in some embodiments from about 90° C. to about 200° C., and in some embodiments, from about 120° C. to about 180° C. as determined in accordance with ISO 75-2:2013 at a load of 1.8 MPa. The polyarylene sulfides likewise typically have a glass transition temperature of from about 50° C. to about 120° C., in some embodiments from about 60° C. to about 115° C., and in some embodiments, from about 70° C. to about 110° C., such as determined by ISO 11357-2:2020, as well as a melting temperature of from about 220° C. to about 340° C., in some embodiments from about 240° C. to about 320° C., and in some embodiments, from about 260° C. to about 300° C., such as determined in accordance with ISO 11357-3:2018.

As indicated above, substantially amorphous polymers may also be employed that lack a distinct melting point temperature. Suitable amorphous polymers may include, for instance, aromatic polycarbonates, which typically contains repeating structural carbonate units of the formula —R¹—O—C(O)—O—. The polycarbonate is aromatic in that at least a portion (e.g., 60% or more) of the total number of R¹ groups contain aromatic moieties and the balance thereof are aliphatic, alicyclic, or aromatic. In one embodiment, for instance, R¹ may a C₆₋₃₀ aromatic group, that is, contains at least one aromatic moiety. Typically, R¹ is derived from a dihydroxy aromatic compound of the general formula HO—R¹—OH, such as those having the specific formula referenced below:

HO-A¹-Y¹-A²-OH

wherein,

A¹ and A² are independently a monocyclic divalent aromatic group; and

Y¹ is a single bond or a bridging group having one or more atoms that separate A¹ from A². In one particular embodiment, the dihydroxy aromatic compound may be derived from the following formula (I):

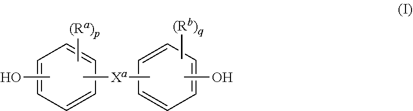

wherein,

R^{a} and R^{b} are each independently a halogen or C₁₋₁₂ alkyl group, such as a C₁₋₃ alkyl group (e.g., methyl) disposed meta to the hydroxy group on each arylene group;

p and q are each independently 0 to 4 (e.g., 1); and

X^{a} represents a bridging group connecting the two hydroxy-substituted aromatic groups, where the bridging group and the hydroxy substituent of each C₆ arylene group are disposed ortho, meta, or para (specifically para) to each other on the C₆ arylene group.

In one embodiment, X^{a} may be a substituted or unsubstituted C₃₋₁₈ cycloalkylidene, a C₁₋₂₅ alkylidene of formula —C(R^{c})(R^{d})— wherein R^{c} and R^{d} are each independently hydrogen, C₁₋₁₂ alkyl, C₁₋₁₂ cycloalkyl, C₇₋₁₂ arylalcyl, C₇₋₁₂ heteroalkyl, or cyclic C₇₋₁₂ heteroarylalkyl, or a group of the formula —C(═R^{e})— wherein R^{e} is a divalent C₁₋₁₂ hydrocarbon group. Exemplary groups of this type include methylene, cyclohexylmethylene, ethylidene, neopentylidene, and isopropylidene, as well as 2-[2.2.1]-bicycloheptylidene, cyclohexylidene, cyclopentylidene, cyclododecylidene, and adamantylidene. A specific example wherein X^{a} is a substituted cycloalkylidene is the cyclohexylidene-bridged, alkyl-substituted bisphenol of the following formula (II):

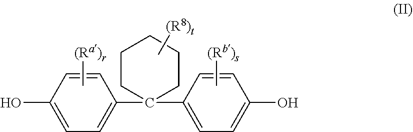

wherein,

R^{a′} and R^{b′} are each independently C₁₋₁₂ alkyl (e.g., C₁₋₄ alkyl, such as methyl), and may optionally be disposed meta to the cyclohexylidene bridging group;

R^{g} is C₁₋₁₂ alkyl (e.g., C₁₋₄ alkyl) or halogen;

r and s are each independently 1 to 4 (e.g., 1); and

t is 0 to 10, such as 0 to 5.

The cyclohexylidene-bridged bisphenol can be the reaction product of two moles of o-cresol with one mole of cyclohexanone. In another embodiment, the cyclohexylidene-bridged bisphenol can be the reaction product of two moles of a cresol with one mole of a hydrogenated isophorone (e.g., 1,1,3-trimethyl-3-cyclohexane-5-one). Such cyclohexane-containing bisphenols, for example the reaction product of two moles of a phenol with one mole of a hydrogenated isophorone, are useful for making polycarbonate polymers with high glass transition temperatures and high heat distortion temperatures.

In another embodiment, X^{a} may be a C₁₋₁₈ alkylene group, a C₃₋₁₈ cycloalkylene group, a fused C₆₋₁₈ cycloalkylene group, or a group of the formula -B¹-W-B²-, wherein B¹ and B² are independently a C₁₋₆ alkylene group and W is a C₃₋₁₂ cycloalkylidene group or a C₆₋₁₆ arylene group.

X^{a} may also be a substituted C₃₋₁₈ cycloalkylidene of the following formula (III):

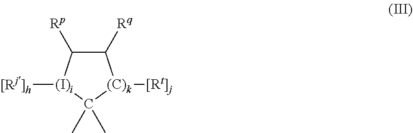

wherein,

R^{r}, R^{p}, R^{q}, and R^{t} are each independently hydrogen, halogen, oxygen, or C₁₋₁₂ organic groups;

l is a direct bond, a carbon, or a divalent oxygen, sulfur, or —N(Z)—, wherein Z is hydrogen, halogen, hydroxy, C₁₋₁₂ alkyl, C₁₋₁₂ alkoxy, or C₁₋₁₂ acyl;

h is 0 to 2;

j is 1 or 2;

i is 0 or 1; and

k is 0 to 3, with the proviso that at least two of R^{r}, R^{p}, R^{q}, and R^{t} taken together are a fused cycloaliphatic, aromatic, or heteroaromatic ring.

Other useful aromatic dihydroxy aromatic compounds include those having the following formula (IV):

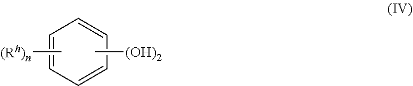

wherein,

R^{h} is independently a halogen atom (e.g., bromine), C₁₋₁₀ hydrocarbyl (e.g., C₁₋₁₀ alkyl group), a halogen-substituted C₁₋₁₀ alkyl group, a C₆₋₁₀ aryl group, or a halogen-substituted C₆₋₁₀ aryl group;

n is 0 to 4.

Specific examples of bisphenol compounds of formula (I) include, for instance, 1,1-bis(4-hydroxyphenyl) methane, 1,1-bis(4-hydroxyphenyl) ethane, 2,2-bis(4-hydroxyphenyl)propane (hereinafter “bisphenol A” or “BPA”), 2,2-bis(4-hydroxyphenyl)butane, 2,2-bis(4-hydroxyphenyl)octane, 1,1-bis(4-hydroxyphenyl)propane, 1,1-bis(4-hydroxyphenyl) n-butane, 2,2-bis(4-hydroxy-1-methylphenyl)propane, 1,1-bis(4-hydroxy-t-butylphenyl)propane, 3,3-bis(4-hydroxyphenyl)phthalimidine, 2-phenyl-3,3-bis(4-hydroxyphenyl)phthalimidine (PPPBP), and 1,1-bis(4-hydroxy-3-methylphenyl)cyclohexane (DMBPC). In one specific embodiment, the polycarbonate may be a linear homopolymer derived from bisphenol A, in which each of A¹ and A² is p-phenylene and Y¹ is isopropylidene in formula (I).

Other examples of suitable aromatic dihydroxy compounds may include, but not limited to, 4,4′-dihydroxybiphenyl, 1,6-dihydroxynaphthalene, 2,6-dihydroxynaphthalene, bis(4-hydroxyphenyl)methane, bis(4-hydroxyphenyl)diphenylmethane, bis(4-hydroxyphenyl)-1-naphthylmethane, 1,2-bis(4-hydroxyphenyl)ethane, 1,1-bis(4-hydroxyphenyl)-1-phenylethane, 2-(4-hydroxyphenyl)-2-(3-hydroxyphenyl)propane, bis(4-hydroxyphenyl)phenylmethane, 2,2-bis(4-hydroxy-3-bromophenyl)propane, 1,1-bis(hydroxyphenyl)cyclopentane, 1,1-bis(4-hydroxyphenyl)cyclohexane, 1,1-bis(4-hydroxyphenyl)isobutene, 1,1-bis(4-hydroxyphenyl)cyclododecane, trans-2,3-bis(4-hydroxyphenyl)-2-butene, 2,2-bis(4-hydroxyphenyl)adamantane, alpha, alpha′-bis(4-hydroxyphenyl)toluene, bis(4-hydroxyphenyl)acetonitrile, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-t-butyl-4-hydroxyphenyl)propane, 2,2-bis(3-cyclohexyl-4-hydroxyphenyl)propane, 2,2-bis(3-allyl-4-hydroxyphenyl)propane, 2,2-bis(3-methoxy-4-hydroxyphenyl)propane, 2,2-bis(4-hydroxyphenyl)hexafluoropropane, 1,1-dichloro-2,2-bis(4-hydroxyphenyl)ethylene, 1,1-dibromo-2,2-bis(4-hydroxyphenyl)ethylene, 1,1-dichloro-2,2-bis(5-phenoxy-4-hydroxyphenyl)ethylene 4,4′-dihydroxybenzophenone, 3,3-bis(4-hydroxyphenyl)-2-butanone, 1,6-bis(4-hydroxyphenyl)-1,6-hexanedione, ethylene glycol bis(4-hydroxyphenyl)ether, bis(4-hydroxyphenyl)ether, bis(4-hydroxyphenyl)sulfide, bis(4-hydroxyphenyl)sulfoxide, bis(4-hydroxyphenyl)sulfone, 9,9-bis(4-hydroxyphenyl)fluorine, 2,7-dihydroxypyrene, 6,6′-dihydroxy-3,3,3′,3′-tetramethylspiro(bis)indane (“spirobiindane bisphenol”), 3,3-bis(4-hydroxyphenyl)phthalimide, 2,6-dihydroxydibenzo-p-dioxin, 2,6-dihydroxythianthrene, 2,7-dihydroxyphenoxathin, 2,7-dihydroxy-9,10-dimethylphenazine, 3,6-dihydroxydibenzofuran, 3,6-dihydroxydibenzothiophene, and 2,7-dihydroxycarbazole, resorcinol, substituted resorcinol compounds such as 5-methyl resorcinol, 5-ethyl resorcinol, 5-propyl resorcinol, 5-butyl resorcinol, 5-t-butyl resorcinol, 5-phenyl resorcinol, 5-cumyl resorcinol, 2,4,5,6-tetrafluoro resorcinol, 2,4,5,6-tetrabromo resorcinol, or the like; catechol; hydroquinone; substituted hydroquinones such as 2-methyl hydroquinone, 2-ethyl hydroquinone, 2-propyl hydroquinone, 2-butyl hydroquinone, 2-t-butyl hydroquinone, 2-phenyl hydroquinone, 2-cumyl hydroquinone, 2,3,5,6-tetramethyl hydroquinone, 2,3,5,6-tetra-t-butyl hydroquinone, 2,3,5,6-tetrafluoro hydroquinone, 2,3,5,6-tetrabromo hydroquinone, etc., as well as combinations thereof.

Aromatic polycarbonates, such as described above, typically have a DTUL value of from about 80° C. to about 300° C., in some embodiments from about 100° C. to about 250° C., and in some embodiments, from about 140° C. to about 220° C., as determined in accordance with ISO 75-2:2013 at a load of 1.8 MPa. The glass transition temperature may also be from about 50° C. to about 250° C., in some embodiments from about 90° C. to about 220° C., and in some embodiments, from about 100° C. to about 200° C., such as determined by ISO 11357-2:2020. Such polycarbonates may also have an intrinsic viscosity of from about 0.1 dl/g to about 6 dl/g, in some embodiments from about 0.2 to about 5 dl/g, and in some embodiments from about 0.3 to about 1 dl/g, such as determined in accordance with ISO 1628-4:1998.

In addition to the polymers referenced above, highly crystalline aromatic polymers may also be employed in the polymer composition. Particularly suitable examples of such polymers are liquid crystalline polymers, which have a high degree of crystallinity that enables them to effectively fill the small spaces of a mold. Liquid crystalline polymers are generally classified as “thermotropic” to the extent that they can possess a rod-like structure and exhibit a crystalline behavior in their molten state (e.g., thermotropic nematic state). Such polymer typically have a DTUL value of from about 120° C. to about 340° C., in some embodiments from about 140° C. to about 320° C., and in some embodiments, from about 150° C. to about 300° C., as determined in accordance with ISO 75-2:2013 at a load of 1.8 MPa. The polymers also have a relatively high melting temperature, such as from about 250° C. to about 400° C., in some embodiments from about 280° C. to about 390° C., and in some embodiments, from about 300° C. to about 380° C. Such polymers may be formed from one or more types of repeating units as is known in the art.

A liquid crystalline polymer may, for example, contain one or more aromatic ester repeating units, typically in an amount of from about 60 mol. % to about 99.9 mol. %, in some embodiments from about 70 mol. % to about 99.5 mol. %, and in some embodiments, from about 80 mol. % to about 99 mol. % of the polymer. The aromatic ester repeating units may be generally represented by the following Formula (V):

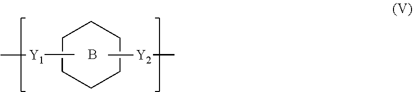

wherein,

ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and

Y₁ and Y₂ are independently O, C(O), NH, C(O)HN, or NHC(O).

Typically, at least one of Y₁ and Y₂ are C(O). Examples of such aromatic ester repeating units may include, for instance, aromatic dicarboxylic repeating units (Y₁ and Y₂ in Formula V are C(O)), aromatic hydroxycarboxylic repeating units (Y₁ is O and Y₂ is C(O) in Formula V), as well as various combinations thereof.

Aromatic dicarboxylic repeating units, for instance, may be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, terephthalic acid (“TA”), isophthalic acid (“IA”), and 2,6-naphthalenedicarboxylic acid (“NDA”). When employed, repeating units derived from aromatic dicarboxylic acids (e.g., IA, TA, and/or NDA) typically constitute from about 5 mol. % to about 60 mol. %, in some embodiments from about 10 mol. % to about 55 mol. %, and in some embodiments, from about 15 mol. % to about 50% of the polymer.

Aromatic hydroxycarboxylic repeating units may also be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. Particularly suitable aromatic hydroxycarboxylic acids are 4-hydroxybenzoic acid (“HBA”) and 6-hydroxy-2-naphthoic acid (“HNA”). When employed, repeating units derived from hydroxycarboxylic acids (e.g., HBA and/or HNA) typically constitute from about 10 mol. % to about 85 mol. %, in some embodiments from about 20 mol. % to about 80 mol. %, and in some embodiments, from about 25 mol. % to about 75% of the polymer.

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). When employed, repeating units derived from aromatic diols (e.g., HQ and/or BP) typically constitute from about 1 mol. % to about 30 mol. %, in some embodiments from about 2 mol. % to about 25 mol. %, and in some embodiments, from about 5 mol. % to about 20% of the polymer. Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). When employed, repeating units derived from aromatic amides (e.g., APAP) and/or aromatic amines (e.g., AP) typically constitute from about 0.1 mol. % to about 20 mol. %, in some embodiments from about 0.5 mol. % to about 15 mol. %, and in some embodiments, from about 1 mol. % to about 10% of the polymer. It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids, diols, amides, amines, etc. Of course, in other embodiments, the polymer may be “wholly aromatic” in that it lacks repeating units derived from non-aromatic (e.g., aliphatic or cycloaliphatic) monomers.

In one particular embodiment, the liquid crystalline polymer may be formed from repeating units derived from 4-hydroxybenzoic acid (“HBA”) and terephthalic acid (“TA”) and/or isophthalic acid (“IA”), as well as various other optional constituents. The repeating units derived from 4-hydroxybenzoic acid (“HBA”) may constitute from about 10 mol. % to about 80 mol. %, in some embodiments from about 30 mol. % to about 75 mol. %, and in some embodiments, from about 45 mol. % to about 70% of the polymer. The repeating units derived from terephthalic acid (“TA”) and/or isophthalic acid (“IA”) may likewise constitute from about 5 mol. % to about 40 mol. %, in some embodiments from about 10 mol. % to about 35 mol. %, and in some embodiments, from about 15 mol. % to about 35% of the polymer. Repeating units may also be employed that are derived from 4,4′-biphenol (“BP”) and/or hydroquinone (“HQ”) in an amount from about 1 mol. % to about 30 mol. %, in some embodiments from about 2 mol. % to about 25 mol. %, and in some embodiments, from about 5 mol. % to about 20% of the polymer. Other possible repeating units may include those derived from 6-hydroxy-2-naphthoic acid (“HNA”), 2,6-naphthalenedicarboxylic acid (“NDA”), and/or acetaminophen (“APAP”). In certain embodiments, for example, repeating units derived from HNA, NDA, and/or APAP may each constitute from about 1 mol. % to about 35 mol. %, in some embodiments from about 2 mol. % to about 30 mol. %, and in some embodiments, from about 3 mol. % to about 25 mol. % when employed.

Of course, besides aromatic polymers, aliphatic polymers may also be suitable for use as high performance, thermoplastic polymers in the polymer matrix. In one embodiment, for instance, polyamides may be employed that generally have a CO—NH linkage in the main chain and are obtained by condensation of an aliphatic diamine and an aliphatic dicarboxylic acid, by ring opening polymerization of lactam, or self-condensation of an amino carboxylic acid. For example, the polyamide may contain aliphatic repeating units derived from an aliphatic diamine, which typically has from 4 to 14 carbon atoms. Examples of such diamines include linear aliphatic alkylenediamines, such as 1,4-tetramethylenediamine, 1,6-hexanediamine, 1,7-heptanediamine, 1,8-octanediamine, 1,9-nonanediamine, 1,10-decanediamine, 1,11-undecanediamine, 1,12-dodecanediamine, etc.; branched aliphatic alkylenediamines, such as 2-methyl-1,5-pentanediamine, 3-methyl-1,5 pentanediamine, 2,2,4-trimethyl-1,6-hexanediamine, 2,4,4-trimethyl-1,6-hexanediamine, 2,4-dimethyl-1,6-hexanediamine, 2-methyl-1,8-octanediamine, 5-methyl-1,9-nonanediamine, etc.; as well as combinations thereof. Aliphatic dicarboxylic acids may include, for instance, adipic acid, sebacic acid, etc. Particular examples of such aliphatic polyamides include, for instance, nylon-4 (poly-α-pyrrolidone), nylon-6 (polycaproamide), nylon-11 (polyundecanamide), nylon-12 (polydodecanamide), nylon-46 (polytetramethylene adipamide), nylon-66 (polyhexamethylene adipamide), nylon-610, and nylon-612. Nylon-6 and nylon-66 are particularly suitable.

It should be understood that it is also possible to include aromatic monomer units in the polyamide such that it is considered aromatic (contains only aromatic monomer units are both aliphatic and aromatic monomer units). Examples of aromatic dicarboxylic acids may include, for instance, terephthalic acid, isophthalic acid, 2,6-naphthalenedicarboxylic acid, 2,7-naphthalenedicarboxylic acid, 1,4-naphthalenedicarboxylic acid, 1,4-phenylenedioxy-diacetic acid, 1,3-phenylenedioxy-diacetic acid, diphenic acid, 4,4′-oxydibenzoic acid, diphenylmethane-4,4′-dicarboxylic acid, diphenylsulfone-4,4′-dicarboxylic acid, 4,4′-biphenyldicarboxylic acid, etc. Particularly suitable aromatic polyamides may include poly(nonamethylene terephthalamide) (PA9T), poly(nonamethylene terephthalamide/nonamethylene decanediamide) (PA9T/910), poly(nonamethylene terephthalamide/nonamethylene dodecanediamide) (PA9T/912), poly(nonamethylene terephthalamide/11-aminoundecanamide) (PA9T/11), poly(nonamethylene terephthalamide/12-aminododecanamide) (PA9T/12), poly(decamethylene terephthalamide/11-aminoundecanamide) (PA10T/11), poly(decamethylene terephthalamide/12-aminododecanamide) (PA10T/12), poly(decamethylene terephthalamide/decamethylene decanediamide) (PA10T/1010), poly(decamethylene terephthalamide/decamethylene dodecanediamide) (PA10T/1012), poly(decamethylene terephthalamide/tetramethylene hexanediamide) (PA10T/46), poly(decamethylene terephthalamide/caprolactam) (PA10T/6), poly(decamethylene terephthalamide/hexamethylene hexanediamide) (PA10T/66), poly(dodecamethylene terephthalamide/dodecamethylene dodecanediamide) (PA12T/1212), poly(dodecamethylene terephthalamide/caprolactam) (PA12T/6), poly(dodecamethylene terephthalamide/hexamethylene hexanediamide) (PA12T/66), and so forth.

The polyamide employed in the polyamide composition is typically crystalline or semi-crystalline in nature and thus has a measurable melting temperature. The melting temperature may be relatively high such that the composition can provide a substantial degree of heat resistance to a resulting part. For example, the polyamide may have a melting temperature of about 220° C. or more, in some embodiments from about 240° C. to about 325° C., and in some embodiments, from about 250° C. to about 335° C. The polyamide may also have a relatively high glass transition temperature, such as about 30° C. or more, in some embodiments about 40° C. or more, and in some embodiments, from about 45° C. to about 140° C. The glass transition and melting temperatures may be determined as is well known in the art using differential scanning calorimetry (“DSC”), such as determined by ISO Test No. 11357-2:2020 (glass transition) and 11357-3:2018 (melting).

Propylene polymers may also be suitable aliphatic high performance polymers for use in the polymer matrix. Any of a variety of propylene polymers or combinations of propylene polymers may generally be employed in the polymer matrix, such as propylene homopolymers (e.g., syndiotactic, atactic, isotactic, etc.), propylene copolymers, and so forth. In one embodiment, for instance, a propylene polymer may be employed that is an isotactic or syndiotactic homopolymer. The term “syndiotactic” generally refers to a tacticity in which a substantial portion, if not all, of the methyl groups alternate on opposite sides along the polymer chain. On the other hand, the term “isotactic” generally refers to a tacticity in which a substantial portion, if not all, of the methyl groups are on the same side along the polymer chain. In yet other embodiments, a copolymer of propylene with an α-olefin monomer may be employed. Specific examples of suitable α-olefin monomers may include ethylene, 1-butene; 3-methyl-1-butene; 3,3-dimethyl-1-butene; 1-pentene; 1-pentene with one or more methyl, ethyl or propyl substituents; 1-hexene with one or more methyl, ethyl or propyl substituents; 1-heptene with one or more methyl, ethyl or propyl substituents; 1-octene with one or more methyl, ethyl or propyl substituents; 1-nonene with one or more methyl, ethyl or propyl substituents; ethyl, methyl or dimethyl-substituted 1-decene; 1-dodecene; and styrene. The propylene content of such copolymers may be from about 60 mol. % to about 99 mol. %, in some embodiments from about 80 mol. % to about 98.5 mol. %, and in some embodiments, from about 87 mol. % to about 97.5 mol. %. The α-olefin content may likewise range from about 1 mol. % to about 40 mol. %, in some embodiments from about 1.5 mol. % to about 15 mol. %, and in some embodiments, from about 2.5 mol. % to about 13 mol. %.

Suitable propylene polymers are typically those having a DTUL value of from about 80° C. to about 250° C., in some embodiments from about 100° C. to about 220° C., and in some embodiments, from about 110° C. to about 200° C., as determined in accordance with ISO 75-2:2013 at a load of 1.8 MPa. The glass transition temperature of such polymers may likewise be from about 10° C. to about 80° C., in some embodiments from about 15° C. to about 70° C., and in some embodiments, from about 20° C. to about 60° C., such as determined by ISO 11357-2:2020. Further, the melting temperature of such polymers may be from about 50° C. to about 250° C., in some embodiments from about 90° C. to about 220° C., and in some embodiments, from about 100° C. to about 200° C., such as determined by ISO 11357-3:2018.

Oxymethylene polymers may also be suitable aliphatic high performance polymers for use in the polymer matrix. Oxymethylene polymers can be either one or more homopolymers, copolymers, or a mixture thereof. Homopolymers are prepared by polymerizing formaldehyde or formaldehyde equivalents, such as cyclic oligomers of formaldehyde. Copolymers can contain one or more comonomers generally used in preparing polyoxymethylene compositions. Commonly used comonomers include alkylene oxides of 2-12 carbon atoms. If a copolymer is selected, the quantity of comonomer will typically not be more than 20 weight percent, in some embodiments not more than 15 weight percent, and, in some embodiments, about two weight percent. Comonomers can include ethylene oxide and butylene oxide. It is preferred that the homo- and copolymers are: 1) those whose terminal hydroxy groups are end-capped by a chemical reaction to form ester or ether groups; or, 2) copolymers that are not completely end-capped, but that have some free hydroxy ends from the comonomer unit. Typical end groups, in either case, are acetate and methoxy.

B. EMI Filler

As indicated above, an EMI filler that contains carbon fibers is distributed within the polymer matrix. Generally speaking, the carbon fibers may exhibit a high intrinsic thermal conductivity, such as about 200 W/m-k or more, in some embodiments about 500 W/m-K or more, in some embodiments from about 600 W/m-K to about 3,000 W/m-K, and in some embodiments, from about 800 W/m-K to about 1,500 W/m-K, as well as a low intrinsic electrical resistivity (single filament) of less than about 20 μohm-m, in some embodiments less than about 10 μoh-m, in some embodiments from about 0.05 to about 5 μohm-m, and in some embodiments, from about 0.1 to about 2 μohm-m.

The nature of the carbon fibers may vary, such as carbon fibers obtained from cellulose, lignin, polyacrylonitrile (PAN) and pitch. Pitch-based carbon fibers are particularly suitable for use in the polymer composition. Such pitch-based fibers may, for instance, be derived from condensation polycyclic hydrocarbon compounds (e.g., naphthalene, phenanthrene, etc.), condensation heterocyclic compounds (e.g., petroleum-based pitch, coal-based pitch, etc.), and so forth. It may be particularly desirable to employ an optically anisotropic pitch (“mesophase pitch”) as such pitch can form a thermotropic crystal, which allows the pitch to become organized and form linear chains, thereby resulting in fibers that are more sheet-like in nature due to their crystal structure. Among other things, fibers having such a morphology may possess a higher degree of intrinsic thermal conductivity. The mesophase pitch typically contains greater than 90 wt. % mesophase, and in some embodiments, approximately 100 wt. % mesophase pitch, as defined and described by the terminology and methods disclosed by S. Chwastiak et al in Carbon 19, 357-363 (1981). Such pitch-based carbon fibers may be formed using any of a variety of techniques known in the art. For example, the pitch-based fibers may be formed by melt spinning a high purity mesophase pitch at a temperature above the softening point of the raw pitch material, such as about 250° C. or more, and in some embodiments, from about 250° C. to about 350° C. The melt spun fibers may then be subjected to a variety of heat treatment steps to remove impurities, such as oxidization/pre-carbonization to initiate crosslinking and remove impurities, carbonization to remove inorganic elements, and/or graphitization improve alignment and orientation of the crystalline regions. Such heat treatment steps generally occur at a high temperature, such as from about 400° C. to about 2,500° C., and in an inert atmosphere. Examples of such techniques are described, for instance, in U.S. Pat. No. 8,642,682 to Nishihata, et al. and U.S. Pat. No. 7,846,543 to Sano, et al.

In addition to exhibiting a high degree of intrinsic thermal conductivity and low volume resistivity, such fibers also generally have a high degree of tensile strength relative to their mass. For example, the tensile strength of the fibers is typically from about 500 to about 10,000 MPa, in some embodiments from about 600 MPa to about 4,000 MPa, and in some embodiments, from about 800 MPa to about 2,000 MPa, such as determined in accordance with ASTM D4018-17. The fibers may have an average diameter of from about 1 to about 200 micrometers, in some embodiments from about 1 to about 150 micrometers, in some embodiments from about 3 to about 100 micrometers, and in some embodiments, from about 5 to about 50 micrometers. The fibers may be continuous filaments, chopped, or milled. In certain embodiments, for instance, the fibers may be chopped fibers having a volume average length of the fibers may likewise range from about 0.1 to about 15 millimeters, in some embodiments from about 0.5 to about 12 millimeters, and in some embodiments, from about 1 to about 10 millimeters.

The EMI filler is typically present in an amount of from about 1 wt. % to about 75 wt. %, in some embodiments from about 2 wt. % to about 70 wt. %, in some embodiments from about 5 wt. % to about 60 wt. %, in some embodiments from about 6 wt. % to about 50 wt. %, and in some embodiments, from about 10 wt. % to about 30 wt. % of the composition. The polymer matrix may likewise be present in an amount of from about 25 wt. % to about 99 wt. %, in some embodiments from about 30 wt. % to about 98 wt. %, in some embodiments from about 40 wt. % to about 95 wt. %, in some embodiments from about 50 wt. % to about 94 wt. %, and in some embodiments, from about 70 wt. % to about 90 wt. % of the composition. Of course, the exact amount of the EMI filler will generally depend on the nature of the filler and/or thermoplastic polymer(s), as well as the nature of other components in the composition.

If desired, the EMI filler and other optional components as described below (e.g., thermally conductive fillers, flame retardants, stabilizers, reinforcing fibers, pigments, lubricants, etc.) may be melt blended together to form the polymer matrix. The raw materials may be supplied either simultaneously or in sequence to a melt-blending device that dispersively blends the materials. Batch and/or continuous melt blending techniques may be employed. For example, a mixer/kneader, Banbury mixer, Farrel continuous mixer, single-screw extruder, twin-screw extruder, roll mill, etc., may be utilized to blend the materials. One particularly suitable melt-blending device is a co-rotating, twin-screw extruder (e.g., ZSK-30 twin-screw extruder available from Werner & Pfleiderer Corporation of Ramsey, N.J.). Such extruders may include feeding and venting ports and provide high intensity distributive and dispersive mixing.

In certain other embodiments, however, the EMI filler may be combined with the polymer matrix using other techniques. In one particular embodiment, for example, the EMI filler may be in the form of “long fibers”, which generally refers to fibers, filaments, yarns, or rovings (e.g., bundles of fibers) that are not continuous and have a length of from about 1 to about 25 millimeters, in some embodiments, from about 1.5 to about 20 millimeters, in some embodiments from about 2 to about 15 millimeters, and in some embodiments, from about 3 to about 12 millimeters. The nominal diameter of the fibers (e.g., diameter of fibers within a roving) may range from about 1 to about 40 micrometers, in some embodiments from about 2 to about 30 micrometers, and in some embodiments, from about 5 to about 25 micrometers. If desired, the fibers may be in the form of rovings (e.g., bundle of fibers) that contain a single fiber type or different types of fibers. The number of fibers contained in each roving can be constant or vary from roving to roving. Typically, a roving may contain from about 1,000 fibers to about 50,000 individual fibers, and in some embodiments, from about 2,000 to about 40,000 fibers.

Any of a variety of different techniques may generally be employed to incorporate such long fibers into the polymer matrix. The long fibers may be randomly distributed within the polymer matrix, or alternatively distributed in an aligned fashion. In one embodiment, for instance, continuous fibers may initially be impregnated into the polymer matrix to form strands, which are thereafter cooled and then chopped into pellets to that the resulting fibers have the desired length for the long fibers. In such embodiments, the polymer matrix and continuous fibers (e.g., rovings) are typically pultruded through an impregnation die to achieve the desired contact between the fibers and the polymer. Pultrusion can also help ensure that the fibers are spaced apart and aligned in the same or a substantially similar direction, such as a longitudinal direction that is parallel to a major axis of the pellet (e.g., length), which further enhances the mechanical properties. For instance, one embodiment of a pultrusion process may involve the supply of a polymer matrix from an extruder to an impregnation die while continuous fibers are a pulled through the die via a puller device to produce a composite structure. Typical puller devices may include, for example, caterpillar pullers and reciprocating pullers. While optional, the composite structure may also be pulled through a coating die that is attached to an extruder through which a coating resin is applied to form a coated structure. The coated structure may then be pulled through a puller assembly and supplied to a pelletizer that cuts the structure into the desired size for forming the long fiber-reinforced composition.

The nature of the impregnation die employed during the pultrusion process may be selectively varied to help achieved good contact between the polymer matrix and the long fibers. Examples of suitable impregnation die systems are described in detail in Reissue Pat. No. 32,772 to Hawley; U.S. Pat. No. 9,233,486 to Regan, et al.; and U.S. Pat. No. 9,278,472 to Eastep, et al. For instance, a polymer matrix may be supplied to the impregnation die via an extruder. The die is generally operated at temperatures that are sufficient to cause melting and impregnation of the thermoplastic polymer. Typically, the operation temperature of the die is higher than the melt temperature of the polymer matrix. When processed in this manner, the continuous fibers become embedded in the polymer matrix. The mixture is then pulled through the impregnation die to create a fiber-reinforced composition.

Within the impregnation die, it is generally desired that the fibers contact a series of impingement zones. At these zones, the polymer melt may flow transversely through the fibers to create shear and pressure, which significantly enhances the degree of impregnation. This is particularly useful when forming a composite from ribbons of a high fiber content. Typically, the die will contain at least 2, in some embodiments at least 3, and in some embodiments, from 4 to 50 impingement zones per roving to create a sufficient degree of shear and pressure. Although their particular form may vary, the impingement zones typically possess a curved surface, such as a curved lobe, rod, etc. The impingement zones are also typically made of a metal material. To further facilitate impregnation, the fibers may also be kept under tension while present within the impregnation die. The tension may, for example, range from about 5 to about 300 Newtons, in some embodiments from about 50 to about 250 Newtons, and in some embodiments, from about 100 to about 200 Newtons per tow of fibers. Furthermore, the fibers may also pass impingement zones in a tortuous path to enhance shear. For example, the fibers may traverse over the impingement zones in a sinusoidal-type pathway. The angle at which the rovings traverse from one impingement zone to another is generally high enough to enhance shear, but not so high to cause excessive forces that will break the fibers. Thus, for example, the angle may range from about 1° to about 30°, and in some embodiments, from about 5° to about 25°.

C. Other Components

In addition to the components noted above, the polymer matrix may also contain a variety of other components. Examples of such optional components may include, for instance, thermally conductive fillers, reinforcing fibers, impact modifiers, compatibilizers, particulate fillers (e.g., talc, mica, etc.), stabilizers (e.g., antioxidants, UV stabilizers, etc.), flame retardants, lubricants, colorants, flow modifiers, pigments, and other materials added to enhance properties and processability.

As indicated above, the polymer composition of the present invention is capable of achieving a high degree of thermal conductivity without the need for additional thermal conductive fillers. In this regard, the polymer composition may be generally free of additional thermally conductive fillers. Nevertheless, in certain instances, additional thermally conductive fillers may still be employed, albeit typically in a relatively low amount. For example, when employed, additional thermally conductive filler(s) typically constitute no more than about 20 wt. % of the composition, in some embodiments no more than about 10 wt. % of the composition, and in some embodiments, from about 0.01 wt. % to about 5 wt. % the composition. Such additional thermally conductive fillers generally have a high intrinsic thermal conductivity, such as about 50 W/m-K or more, in some embodiments about 100 W/m-K or more, and in some embodiments, about 150 W/m-K or more. Examples of such materials may include, for instance, boron nitride (BN), aluminum nitride (AlN), magnesium silicon nitride (MgSiN₂), graphite (e.g., expanded graphite), silicon carbide (SiC), carbon nanotubes, carbon black, metal oxides (e.g., zinc oxide, magnesium oxide, beryllium oxide, zirconium oxide, yttrium oxide, etc.), metallic powders (e.g., aluminum, copper, bronze, brass, etc.), etc., as well as combinations thereof. The thermally conductive filler may be provided in various forms, such as particulate materials, fibers, etc. For instance, particulate materials may be employed that have an average size (e.g., diameter or length) in the range of about 1 to about 100 micrometers, in some embodiments from about 2 to about 80 micrometers, and in some embodiments, from about 5 to about 60 micrometers, such as determined using laser diffraction techniques in accordance with ISO 13320:2009 (e.g., with a Horiba LA-960 particle size distribution analyzer).

The polymer composition of the present invention is also capable of achieving a high degree of mechanical strength without the need for additional reinforcements (e.g., reinforcing fibers). In this regard, the polymer composition may be generally free of additional reinforcing fibers. Nevertheless, in certain instances, additional reinforcing fibers may still be employed, albeit typically in a relatively low amount. For example, when employed, additional reinforcing fibers typically constitute no more than about 20 wt. % of the composition, in some embodiments no more than about 10 wt. % of the composition, and in some embodiments, from about 0.01 wt. % to about 5 wt. % the composition. Such reinforcing fibers may be formed from materials that are also generally insulative in nature, such as glass, ceramics (e.g., alumina or silica), aramids (e.g., Kevlar®), polyolefins, polyesters, etc., as well as mixtures thereof. Glass fibers are particularly suitable, such as E-glass, A-glass, C-glass, D-glass, AR-glass, R-glass, S1-glass, S2-glass, etc., and mixtures thereof. The reinforcing fibers may be in the form of randomly distributed fibers, such as when such fibers are melt blended with the high performance polymer(s) during the formation of the polymer matrix. Alternatively, the reinforcing fibers may be in the form of long fibers and impregnated with the polymer matrix in a manner such as described above. Regardless, the volume average length of the reinforcing fibers may be from about 1 to about 400 micrometers, in some embodiments from about 50 to about 400 micrometers, in some embodiments from about 80 to about 250 micrometers, in some embodiments from about 100 to about 200 micrometers, and in some embodiments, from about 110 to about 180 micrometers. The fibers may also have an average diameter of about 10 to about 35 micrometers, and in some embodiments, from about 15 to about 30 micrometers.

### II. Electronic Module

As indicated above, the polymer composition may be employed in an electronic module. The module generally contains a housing that receives one or more electronic components (e.g., printed circuit board, antenna elements, radio frequency sensing elements, sensors, light sensing and/or transmitting elements (e.g., fibers optics), cameras, global positioning devices, etc.). The housing may, for instance, include a base that contains a sidewall extending therefrom. A cover may also be supported on the sidewall of the base to define an interior within which the electronic component(s) are received and protected from the exterior environment. Regardless of the particular configuration of the module, the polymer composition of the present invention may be used to form all or a portion of the housing and/or cover. In one embodiment, for instance, the polymer composition of the present invention may be used to form the base and sidewall of the housing. The cover may be formed from the polymer composition of the present invention or from a different material. Notably, one benefit of the present invention is that conventional EMI metal shields (e.g., aluminum plates) and/or heat sinks can be eliminated from the module design, thereby reducing the weight and overall cost of the module. Nevertheless, in certain other embodiments, such additional shields and/or heat sinks may be employed. For example, the cover may contain a metal component (e.g., aluminum plate) in some cases.

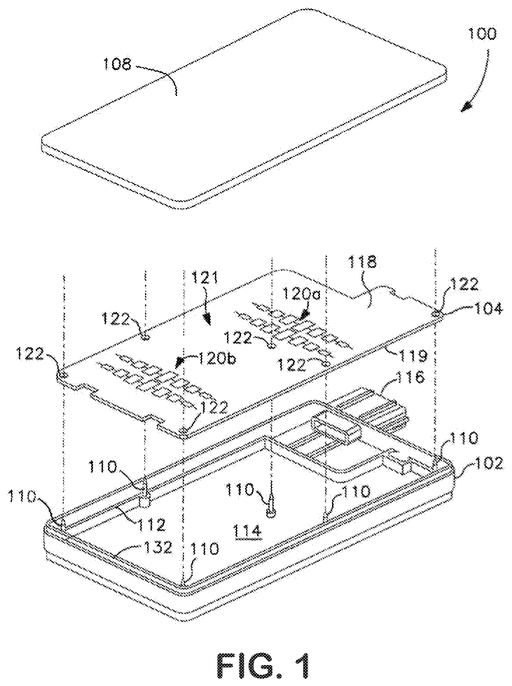

Referring to FIG. 1, for instance, one particular embodiment of an electronic module 100 is shown that may incorporate the polymer composition of the present invention. The electronic module 100 includes a housing 102 that contains sidewalls 132 extending from a base 114. If desired, the housing 102 may also contain a shroud 116 that can accommodate an electrical connector (not shown). Regardless, a printed circuit board (“PCB”) is received within the interior of the module 100 and attached to housing 102. More particularly, the circuit board 104 contains holes 122 that are aligned with and receive posts 110 located on the housing 102. The circuit board 104 has a first surface 118 on which electrical circuitry 121 is provided to enable radio frequency operation of the module 100. For example, the RF circuitry 121 can include one or more antenna elements 120a and 120b. The circuit board 104 also has a second surface 119 that opposes the first surface 118 and may optionally contain other electrical components, such as components that enable the digital electronic operation of the module 100 (e.g., digital signal processors, semiconductor memories, input/output interface devices, etc.). Alternatively, such components may be provided on an additional printed circuit board. A cover 108 may also be employed that is disposed over the circuit board 104 and attached to the housing 102 (e.g., sidewall) through known techniques, such as by welding, adhesives, etc., to seal the electrical components within the interior. As indicated above, the polymer composition may be used to form all or a portion of the cover 108 and/or the housing 102. As noted above, because it possesses the unique combination of EMI shielding effectiveness and thermal conductivity, conventional EMI shields (e.g., aluminum plates) and/or heat sinks may be eliminated.

The electronic module may be used in a wide variety of applications. For example, the electronic module may be employed in an automotive vehicle (e.g., electric vehicle). When used in automotive applications, for instance, the electronic module may be used to sense the positioning of the vehicle relative to one or more three-dimensional objects. In this regard, the module may contain radio frequency sensing components, light detection or optical components, cameras, antenna elements, etc., as well as combinations thereof. For example, the module may be a radio detection and ranging (“radar”) module, light detection and ranging (“lidar”) module, camera module, global positioning module, etc., or it may be an integrated module that combines two or more of these components. Such modules may thus employ a housing that receives one or more types of electronic components (e.g., printed circuit board, antenna elements, radio frequency sensing devices, sensors, light sensing and/or transmitting elements (e.g., fibers optics), cameras, global positioning devices, etc.). In one embodiment, for example, a lidar module may be formed that contains a fiber optic assembly for receiving and transmitting light pulses that is received within the interior of a housing/cover assembly in a manner similar to the embodiments discussed above. Similarly, a radar module typically contains one or more printed circuit boards having electrical components dedicated to handling radio frequency (RF) radar signals, digital signal processing tasks, etc.

The electronic module may also be employed in a 5G system. For example, the electronic module may be an antenna module, such as macrocells (base stations), small cells, microcells or repeaters (femtocells), etc. As used herein, “5G” generally refers to high speed data communication over radio frequency signals. 5G networks and systems are capable of communicating data at much faster rates than previous generations of data communication standards (e.g., “4G, “LTE”). Various standards and specifications have been released quantifying the requirements of 5G communications. As one example, the International Telecommunications Union (ITU) released the International Mobile Telecommunications-2020 (“IMT-2020”) standard in 2015. The IMT-2020 standard specifies various data transmission criteria (e.g., downlink and uplink data rate, latency, etc.) for 5G. The IMT-2020 Standard defines uplink and downlink peak data rates as the minimum data rates for uploading and downloading data that a 5G system must support. The IMT-2020 standard sets the downlink peak data rate requirement as 20 Gbit/s and the uplink peak data rate as 10 Gbit/s. As another example, 3^{rd} Generation Partnership Project (3GPP) recently released new standards for 5G, referred to as “5G NR.” 3GPP published “Release 15” in 2018 defining “Phase 1” for standardization of 5G NR. 3GPP defines 5G frequency bands generally as “Frequency Range 1” (FR1) including sub-6 GHz frequencies and “Frequency Range 2” (FR2) as frequency bands ranging from 20-60 GHz. However, as used herein “5G frequencies” can refer to systems utilizing frequencies greater than 60 GHz, for example ranging up to 80 GHz, up to 150 GHz, and up to 300 GHz. As used herein, “5G frequencies” can refer to frequencies that are about 1.8 GHz or more, in some embodiments about 2.0 GHz or more, in some embodiments about 3.0 GHz or higher, in some embodiments from about 3 GHz to about 300 GHz, or higher, in some embodiments from about 4 GHz to about 80 GHz, in some embodiments from about 5 GHz to about 80 GHz, in some embodiments from about 20 GHz to about 80 GHz, and in some embodiments from about 28 GHz to about 60 GHz.

5G antenna systems generally employ high frequency antennas and antenna arrays for use in a 5G component, such as macrocells (base stations), small cells, microcells or repeaters (femtocell), etc., and/or other suitable components of 5G systems. The antenna elements/arrays and systems can satisfy or qualify as “5G” under standards released by 3GPP, such as Release 15 (2018), and/or the IMT-2020 Standard. To achieve such high speed data communication at high frequencies, antenna elements and arrays generally employ small feature sizes/spacing (e.g., fine pitch technology) that can improve antenna performance. For example, the feature size (spacing between antenna elements, width of antenna elements) etc. is generally dependent on the wavelength (“λ”) of the desired transmission and/or reception radio frequency propagating through the substrate on which the antenna element is formed (e.g., nλ/4 where n is an integer). Further, beamforming and/or beam steering can be employed to facilitate receiving and transmitting across multiple frequency ranges or channels (e.g., multiple-in-multiple-out (MIMO), massive MIMO). The high frequency 5G antenna elements can have a variety of configurations. For example, the 5G antenna elements can be or include co-planar waveguide elements, patch arrays (e.g., mesh-grid patch arrays), other suitable 5G antenna configurations. The antenna elements can be configured to provide MIMO, massive MIMO functionality, beam steering, etc. As used herein “massive” MIMO functionality generally refers to providing a large number transmission and receiving channels with an antenna array, for example 8 transmission (Tx) and 8 receive (Rx) channels (abbreviated as 8×8). Massive MIMO functionality may be provided with 8×8, 12×12, 16×16, 32×32, 64×64, or greater.

The antenna elements may be fabricated using a variety of manufacturing techniques. As one example, the antenna elements and/or associated elements (e.g., ground elements, feed lines, etc.) can employ fine pitch technology. Fine pitch technology generally refers to small or fine spacing between their components or leads. For example, feature dimensions and/or spacing between antenna elements (or between an antenna element and a ground plane) can be about 1,500 micrometers or less, in some embodiments 1,250 micrometers or less, in some embodiments 750 micrometers or less (e.g., center-to-center spacing of 1.5 mm or less), 650 micrometers or less, in some embodiments 550 micrometers or less, in some embodiments 450 micrometers or less, in some embodiments 350 micrometers or less, in some embodiments 250 micrometers or less, in some embodiments 150 micrometers or less, in some embodiments 100 micrometers or less, and in some embodiments 50 micrometers or less. However, it should be understood that feature sizes and/or spacings that are smaller and/or larger may also be employed. As a result of such small feature dimensions, antenna configurations and/or arrays can be achieved with a large number of antenna elements in a small footprint. For example, an antenna array can have an average antenna element concentration of greater than 1,000 antenna elements per square centimeter, in some embodiments greater than 2,000 antenna elements per square centimeter, in some embodiments greater than 3,000 antenna elements per square centimeter, in some embodiments greater than 4,000 antenna elements per square centimeter, in some embodiments greater than 6,000 antenna elements per square centimeter, and in some embodiments greater than about 8,000 antenna elements per square centimeter. Such compact arrangement of antenna elements can provide a greater number of channels for MIMO functionality per unit area of the antenna area. For example, the number of channels can correspond with (e.g., be equal to or proportional with) the number of antenna elements.

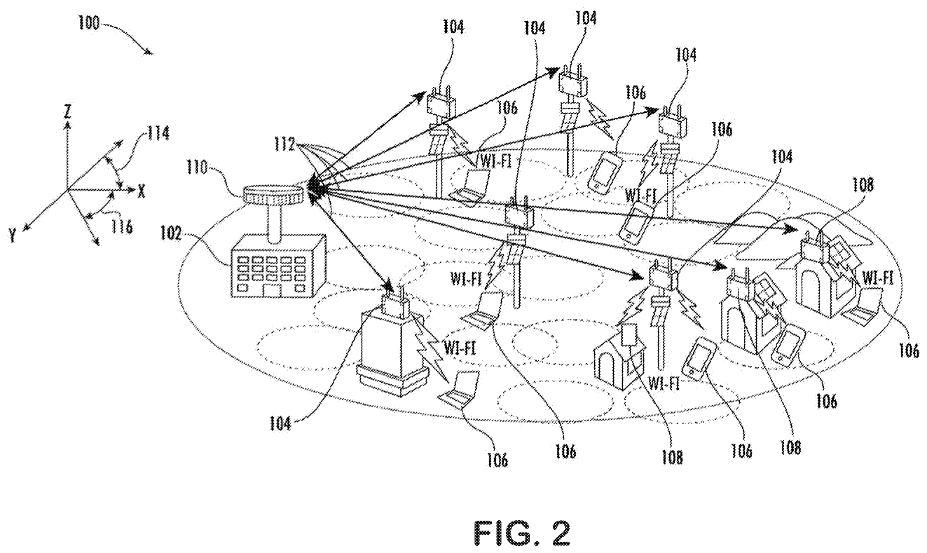

Referring to FIG. 2, for example, a 5G antenna system 100 can include a base station 102, one or more relay stations 104, one or more user computing devices 106, one or more Wi-Fi repeaters 108 (e.g., “femtocells”), and/or other suitable antenna components for the 5G antenna system 100. The relay stations 104 can be configured to facilitate communication with the base station 102 by the user computing devices 106 and/or other relay stations 104 by relaying or “repeating” signals between the base station 102 and the user computing devices 106 and/or relay stations 104. The base station 102 can include a MIMO antenna array 110 configured to receive and/or transmit radio frequency signals 112 with the relay station(s) 104, Wi-Fi repeaters 108, and/or directly with the user computing device(s) 106. The user computing device 306 is not necessarily limited by the present invention and include devices such as 5G smartphones. The MIMO antenna array 110 can employ beam steering to focus or direct radio frequency signals 112 with respect to the relay stations 104. For example, the MIMO antenna array 110 can be configured to adjust an elevation angle 114 with respect to an X-Y plane and/or a heading angle 116 defined in the Z-Y plane and with respect to the Z direction. Similarly, one or more of the relay stations 104, user computing devices 106, Wi-Fi repeaters 108 can employ beam steering to improve reception and/or transmission ability with respect to MIMO antenna array 110 by directionally tuning sensitivity and/or power transmission of the device 104, 106, 108 with respect to the MIMO antenna array 110 of the base station 102 (e.g., by adjusting one or both of a relative elevation angle and/or relative azimuth angle of the respective devices).

The present invention may be better understood with reference to the following examples.

### Test Methods

Thermal Conductivity:

In-plane and through-plane thermal conductivity values are determined in accordance with ASTM E1461-13.

Electromagnetic Interference (“EMI”) Shielding:

EMI shielding effectiveness may be determined in accordance with ASTM D4935-18 at frequency ranges ranging from 1.5 GHz to 10 GHz (e.g., 5 GHz). The thickness of the parts tested may vary, such as 1 millimeter, 1.6 millimeters, or 3 millimeters. The test may be performed using an EM-2108 standard test fixture, which is an enlarged section of coaxial transmission line and available from various manufacturers, such as Electro-Metrics. The measured data relates to the shielding effectiveness due to a plane wave (far field EM wave) from which near field values for magnetic and electric fields may be inferred.

Surface/Volume Resistivity:

The surface and volume resistivity values are generally determined in accordance with ASTM D257-14. For example, a standard specimen (e.g., 1 meter cube) may be placed between two electrodes. A voltage may be applied for sixty (60) seconds and the resistance may be measured. The surface resistivity is the quotient of the potential gradient (in V/m) and the current per unit of electrode length (in A/m), and generally represents the resistance to leakage current along the surface of an insulating material. Because the four (4) ends of the electrodes define a square, the lengths in the quotient cancel and surface resistivities are reported in ohms, although it is also common to see the more descriptive unit of ohms per square. Volume resistivity may also be determined as the ratio of the potential gradient parallel to the current in a material to the current density. In SI units, volume resistivity is numerically equal to the direct-current resistance between opposite faces of a one-meter cube of the material (ohm-m).

Tensile Modulus, Tensile Stress, and Tensile Elongation at Break:

Tensile properties may be tested according to ISO 527-1:2019 (technically equivalent to ASTM D638-14). Modulus and strength measurements may be made on a dogbone-shaped test strip sample having a length of 170/190 mm, thickness of 4 mm, and width of 10 mm. The testing temperature may be −30° C., 23° C., or 80° C. and the testing speeds may be 1 or 5 mm/min.

Flexural Modulus, Flexural Elongation at Break, and Flexural Stress:

Flexural properties may be tested according to ISO 178:2019 (technically equivalent to ASTM D790-17). This test may be performed on a 64 mm support span. Tests may be run on the center portions of uncut ISO 3167 multi-purpose bars. The testing temperature may be −30° C., 23° C., or 80° C. and the testing speed may be 2 mm/min.

Charpy Impact Strength:

Charpy properties may be tested according to ISO 179-1:2010) (technically equivalent to ASTM D256-10, Method B). This test may be run using a Type 1 specimen size (length of 80 mm, width of 10 mm, and thickness of 4 mm). Specimens may be cut from the center of a multi-purpose bar using a single tooth milling machine. The testing temperature may be −30° C., 23° C., or 80° C.

Deflection Temperature Under Load (“DTUL”):

The deflection under load temperature may be determined in accordance with ISO 75-2:2013 (technically equivalent to ASTM D648-07). More particularly, a test strip sample having a length of 80 mm, width of 10 mm, and thickness of 4 mm may be subjected to an edgewise three-point bending test in which the specified load (maximum outer fibers stress) was 1.8 Megapascals. The specimen may be lowered into a silicone oil bath where the temperature is raised at 2° C. per minute until it deflects 0.25 mm (0.32 mm for ISO Test No. 75-2:2013).

### Example 1

Sample 1 is a commercially available polymer composition that contains approximately 75-80 wt. % of a mixture of polyamides (20 wt. % nylon 6 and 80 wt. % nylon 6,6), 20 wt. % carbon fibers, and 0-5 wt. % of other additives. The composition is formed by melt-processing the components in an extruder. The resulting composition is then injection molded into a shaped part for use in a power converter.

### Example 2

Sample 2 is a commercially available polymer composition that contains approximately 80-85 wt. % of polybutylene terephthalate (PBT), 15 wt. % carbon fibers, and 0-5 wt. % of other additives. The composition is formed by melt-processing the components in an extruder. The resulting composition is then injection molded into a shaped part for use in a power converter.

### Example 3

Sample 3 is a commercially available polymer composition that contains approximately 30-40 wt. % of a thermotropic liquid crystalline polymer (LCP) and 60-70 wt. % mesophase pitch-based carbon fibers. The composition is formed by melt-processing the components in an extruder. The resulting composition is then injection molded into a shaped part for use in an electronics module.

Samples 1-3 were also tested for mechanical properties, thermal properties, and electrical properties as described herein. The results are set forth below in Tables 1-3.

TABLE 1
Mechanical and Thermal Properties

| | | | | | | | | | Thermal |
|---|---|---|---|---|---|---|---|---|---|
| | | | | | | | | DTUL | Conductivity |
| | Tensile | Tensile | Tensile | Flex | Flex | Unnotched | Notched | (° C.) | (in-plane, flow |
| | Strength | Modulus | Elongation | Strength | Modulus | Charpy | Charpy | @1.8 | direction) |
| Sample | (MPa) | (MPa) | (%) | (MPa) | (MPa) | (kJ/m²) | (kJ/m²) | MPa | (W/mK) |
| 1 | 205 | 14,900 | 2.7 | — | — | — | 8 | 240 | — |
| 2 | 135 | 12,500 | 3.4 | — | — | — | 5 | 65 (at 8 | — |
| | | | | | | | | MPa) | |
| 3 | 81 | 21,000 | 0.4 | 160 | 41,000 | 8.5 | — | 268 | 16.5 |

TABLE 2
Electrical Properties

| | | | Average EMI | Average EMI | Average EMI | |
|---|---|---|---|---|---|---|
| | | | Shielding | Shielding | Shielding | |
| | EMI Shielding | EMI Shielding | Effectiveness (SE) | Effectiveness (SE) | Effectiveness (SE) | |
| | Effectiveness | Effectiveness | at 1 mm thickness | at 1.6 mm thickness | at 3 mm thickness | |
| | (SE) at 5 GHz | (SE) at 5 GHz | for frequency | for frequency | for frequency | Volume |
| | and 1 mm | and 1.6 mm | range of | range of | range of | Resistivity |
| Sample | thickness | thickness | 1.5 GHz-10 GHz | 1.5 GHZ-10 GHZ | 1 GHz-18 GHz | (ohm-cm) |
| 1 | 44.1 | 46.4 | 42.2 | 45.5 | 49.6 | 1,000 |
| 2 | 43.0 | 43.5 | 40.3 | 42.9 | 37.2 | 20,000 |
| 3 | — | — | — | — | — | 0.1 |

TABLE 3
Electrical Properties (2-16 GHz)

| | EMI Shielding Effectiveness (SE) at 3 mm thickness | | | | | | | |
|---|---|---|---|---|---|---|---|---|
| Sample | 2 GHz | 4 GHz | 6 GHz | 8 GHz | 10 GHz | 12 GHz | 14 GHz | 16 GHz |
| 1 | 33.79 | 32.93 | 29.88 | 34.96 | 39.22 | 41.88 | 49.56 | 50.38 |
| 2 | 24.31 | 20.84 | 19.71 | 17.07 | 20.71 | 24.66 | 26.80 | 27.43 |

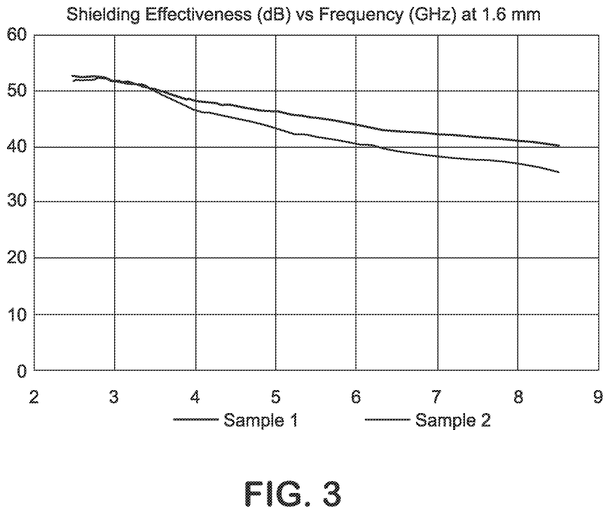

FIG. 3 also shows the shielding effectiveness (“SE”) for Samples 1-2 (thickness of 1.6 mm) over a frequency range from 1.5 MHz to 10 GHz.

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. An electronic module comprising a housing that receives at least one electronic component, wherein the housing contains a polymer composition that includes an electromagnetic interference filler distributed within a polymer matrix, wherein the electromagnetic interference filler includes a plurality of carbon fibers and the polymer matrix contains a thermoplastic polymer, and further wherein the composition exhibits an electromagnetic interference shielding effectiveness of about 30 decibels or more, as determined in accordance with ASTM D4935-18 at a frequency of 5 GHz and thickness of 1.6 millimeters, and an in-plane thermal conductivity of about 1 W/m-K or more, as determined in accordance with ASTM E 1461-13.

2. The electronic module of claim 1, wherein the polymer composition exhibits an average electromagnetic interference shielding effectiveness of about 30 decibels or more over a frequency range of from about 1.5 GHz to about 10 GHz and at a thickness of 1.6 millimeters.

3. The electronic module of claim 1, wherein the polymer composition exhibits a Charpy unnotched impact strength of about 20 kJ/m² or more as determined in accordance with ISO Test No. 179-1:2010 at a temperature of about 23° C.

4. The electronic module of claim 1, wherein the polymer composition exhibits a tensile strength of about 50 MPa or more as determined in accordance with ISO Test No. 527-1:2019 at a temperature of about 23° C.

5. The electronic module of claim 1, wherein the polymer composition exhibits a volume resistivity of about 25,000 oh-cm or less as determined in accordance with ASTM D257-14.

6. The electronic module of claim 1, wherein the polymer composition exhibits a volume resistivity of about 1,000 oh-cm or less as determined in accordance with ASTM D257-14.

7. The electronic module of claim 1, wherein the polymer composition exhibits a dielectric constant of about 4 or less and/or dissipation factor of about 0.001 or less at a frequency of 2 GHz.

8. The electronic module of claim 1, wherein the thermoplastic polymer has a deflection temperature under load of about 40° C. or more as determined in accordance with ISO 75-2:2013 at a load of 1.8 MPa.

9. The electronic module of claim 1, wherein the thermoplastic polymer has a glass transition temperature of about 10° C. or more.

10. The electronic module of claim 1, wherein the thermoplastic polymer has a melting temperature of about 140° C. or more.

11. The electronic module of claim 1, wherein the thermoplastic polymer includes an aromatic polymer.

12. The electronic module of claim 11, wherein the aromatic polymer is an aromatic polyester.

13. The electronic module of claim 12, wherein the aromatic polyester is poly(ethylene terephthalate), poly(1,4-butylene terephthalate), poly(1,3-propylene terephthalate), poly(1,4-butylene 2,6-naphthalate), poly(ethylene 2,6-naphthalate), poly(1,4-cyclohexylene dimethylene terephthalate), or a combination thereof.

14. The electronic module of claim 11, wherein the aromatic polymer is a polyarylene sulfide.

15. The electronic module of claim 11, wherein the aromatic polymer is an aromatic polycarbonate.

16. The electronic module of claim 11, wherein the aromatic polymer is a thermotropic liquid crystalline polymer.

17. The electronic module of claim 11, wherein the aromatic polymer is an aromatic polyamide.

18. The electronic module of claim 1, wherein the thermoplastic polymer includes an aliphatic polymer.

19. The electronic module of claim 18, wherein the aliphatic polymer includes an aliphatic polyamide.

20. The electronic module of claim 1, wherein the electromagnetic interference filler constitutes from about 1 wt. % to about 75 wt. % of the composition and the polymer matrix constitutes from about 25 wt. % to about 99 wt. % of the composition.

21. The electronic module of claim 1, wherein the carbon fibers having an intrinsic thermal conductivity of about 200 W/m-K or more.

22. The electronic module of claim 1, wherein the carbon fibers have an electrical resistivity of about 20 μohm-m or less.

23. The electronic module of claim 1, wherein the carbon fibers are derived from pitch.

24. The electronic module of claim 23, wherein the pitch includes mesophase pitch.

25. The electronic module of claim 1, wherein the carbon fibers exhibit a tensile strength of from about 500 to about 10,000 MPa as determined in accordance with ASTM D4018-17.

26. The electronic module of claim 1, wherein the carbon fibers have an average diameter of from about 1 to about 200 micrometers.

27. The electronic module of claim 1, wherein the polymer composition is free of glass fibers.

28. The electronic module of claim 1, wherein the polymer composition is free of additional thermally conductive fillers.

29. The electronic module of claim 1, wherein the housing includes a base that contains a sidewall extending therefrom and an optional cover supported by the sidewall.

30. The electronic module of claim 29, wherein the base, sidewall, cover, or a combination thereof contain the polymer composition.

31. The electronic module of claim 1, wherein the module is free of a metal EMI shield and/or a heat sink.

32. The electronic module of claim 1, wherein the electronic component includes an antenna element configured to transmit and receive 5G radio frequency signals.

33. The electronic module of claim 32, wherein the module is a base station, small cell, or femtocell.

34. A 5G system comprising the electronic module of claim 33.

35. The electronic module of claim 1, wherein the electronic component includes a radio frequency sensing component.

36. The electronic module of claim 35, wherein the module is a radar module.

37. The electronic module of claim 1, wherein the electronic component includes a fiber optic assembly for receiving and transmitting light pulses.

38. The electronic module of claim 37, wherein the electronic module is a lidar module.

39. The electronic module of claim 1, wherein the electronic component includes a camera.
